(19) United States
(12) Patent Application Publication
(10) Pub. No.: US 2008/0185722 A1
(43) Pub. Date: Aug. 7, 2008

(54) Formation process of interconnect structures with air-gaps and sidewall spacers

(76) Inventors: Chung-Shi Liu, Hsin-Chu (TW); Chen-Hua Yu, Hsin-Chu (TW); Yuh-Jier Mii, Hsin-Chu (TW); Yuan-Chen Sun, Hsin Chu (TW)

Correspondence Address: SLATER & MATSIL, L.L.P., 17950 PRESTON ROAD, SUITE 1000, DALLAS, TX, 75252, US

(21) Appl. No.: 11/702,264

(22) Filed: Feb. 5, 2007

(51) Int. Cl. H01L 23/528

(52) U.S. Cl. 257/751; 257/E23.144; 257/E23.151

(57) ABSTRACT

An integrated circuit structure having air gaps is provided. The integrated circuit includes a conductive line; a sidewall spacer on a sidewall of the conductive line, wherein the sidewall spacer comprises a dielectric material; an air-gap horizontally adjoining the sidewall spacer; and a dielectric layer on the air-gap.

### TECHNICAL FIELD

This invention relates generally to integrated circuits, and more particularly to structure and formation methods of interconnect structures having air-gaps.

### BACKGROUND

As the semiconductor industry introduces new generations of integrated circuits (ICs) having higher performance and greater functionality, the density of the elements that form those ICs is increased, while the dimensions, sizes and spacing between components or elements are reduced. In the past, such reductions were limited only by the ability to define the structures photo-lithographically, device geometries having smaller dimensions created new limiting factors. For example, for any two adjacent conductive features, as the distance between the conductive features decreases, the resulting capacitance (a function of the dielectric constant (k value) of the insulating material divided by the distance between the conductive features) increases. This increased capacitance results in increased capacitive coupling between the conductors, increased power consumption, and an increase in the resistive-capacitive (RC) time constant. Therefore, the continual improvement in semiconductor IC performance and functionality is dependent upon developing materials with low k values.

Since the substance with the lowest dielectric constant is air (k=1.0), low-k dielectric materials typically comprise porous materials. Furthermore, air-gaps are formed to further reduce effective k value of interconnect structures.

FIGS. 1A through 1C illustrate a first process for forming an interconnect structure with air-gaps. Referring to FIG. 1A, copper lines 4 and corresponding diffusion barrier layers (not shown) are formed in an inter-metal dielectric 6, which has a low k value, and contains a high concentration of carbon. During the formation of copper lines 4, portions 8 of inter-metal dielectric 6, which are exposed during the formation of copper lines 4, are damaged, and hence have a low concentration of carbon. The damaged portions 8 may be etched by HF to form air-gaps 10, as illustrated in FIG. 1B. Subsequently, as shown in FIG. 1C, dielectric layer 11 is formed, and air-gaps 10 are sealed.

Although the formation of air-gaps 10 reduces the parasitic capacitance of the interconnect structure, the conventional process suffers drawbacks. Due to the formation of air-gaps 10, no dielectric layer is formed against sidewalls of copper lines 4. Without the back pressure provided by the dielectric layer, electro-migration (EM) is increased, and time dependent dielectric breakdown (TDDB) performance of the interconnect structure is adversely affected. A further problem is that in subsequent processes for forming overlying vias on the copper lines 4, if misalignment occurs, the vias may land on air-gaps 10, resulting in copper being plated into air-gaps 10. This causes copper to be in direct contact with low-k inter-metal dielectric layer 6, hence the diffusion of copper into low-k inter-metal dielectric layer 6.

FIGS. 2A and 2B illustrate a second process for forming air-gaps. In FIG. 2A, copper lines 4 are formed in a thermal-decomposable dielectric layer 12, which is covered by a permeable hard mask layer 14. The substrate is then heated, and thermal-decomposable dielectric layer 12 decomposes and evaporates through permeable hard mask layer 14. Air-gaps 16 are thus formed, as illustrated in FIG. 2B.

FIG. 3 illustrates a third process for forming air-gaps. Copper lines 4 are formed in a thermal-decomposable dielectric layer 12 and are covered by metal caps 18. Permeable inter-layer dielectric 17 is then formed. In subsequent process steps, the substrate is heated. Thermal-decomposable dielectric layer 12 decomposes and evaporates through permeable inter-layer dielectric 17, and thus air-gaps are formed.

The conventional processes illustrated in FIGS. 2A through 3 have similar problems as in the first conventional process. No dielectric layers are formed against sidewalls of copper lines 4. Without the back pressure provided by the dielectric layer, the EM performance and TDDB performance are adversely affected. In addition, misalignment of the overlying vias will cause copper to be formed in air-gaps, which will significantly reduce the distances between metal lines, hence an increase in parasitic capacitances.

Accordingly, what is needed in the art is an interconnect structure that may incorporate air-gaps thereof to take advantage of the benefits associated with reduced parasitic capacitances while at the same time overcoming the deficiencies of the prior art.

### SUMMARY OF THE INVENTION

In accordance with one aspect of the present invention, an integrated circuit structure includes a conductive line; a sidewall spacer on a sidewall of the conductive line, wherein the sidewall spacer comprises a dielectric material; an air-gap horizontally adjoining the sidewall spacer; and a dielectric layer on the air-gap.

In accordance with another aspect of the present invention, an integrated circuit structure includes a semiconductor substrate; a first conductive line; a first sidewall spacer on a sidewall of the first conductive line; a second conductive line horizontally spaced apart from the first conductive line; a second sidewall spacer on a sidewall of the second conductive line; an air-gap horizontally adjoining the first and the second sidewall spacers; and a permeable dielectric layer on and adjoining the air-gap.

In accordance with yet another aspect of the present invention, an integrated circuit structure includes a conductive line; a sidewall spacer on a sidewall of the conductive line; an air-gap horizontally adjoining the sidewall spacer; a permeable mask directly on the air-gap, wherein the sidewall spacer extends on a sidewall of the permeable mask; an etch stop layer on the conductive line and the permeable mask; and an inter-metal dielectric over the conductive line and the permeable mask.

The advantageous features of the present invention include reduced electro-migration and improved time dependent dielectric breakdown.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A, 1B and 1C illustrate a first conventional process for forming air-gaps, wherein damaged low-k dielectric portions are etched to form air-gaps;

FIGS. 2A and 2B illustrate a second conventional process for forming air-gaps, wherein air-gaps are formed by removing a thermal-decomposable material through a permeable hard mask layer;

FIG. 3 illustrates a third conventional process for forming air-gaps, wherein air-gaps are formed by removing a thermal-decomposable material through a permeable inter-metal dielectric;

FIGS. 4 through 10 are cross-sectional views of intermediate stages in the manufacturing of a first embodiment of the present invention; and

FIGS. 11 through 16 are cross-sectional views of intermediate stages in the manufacturing of a second embodiment of the present invention.

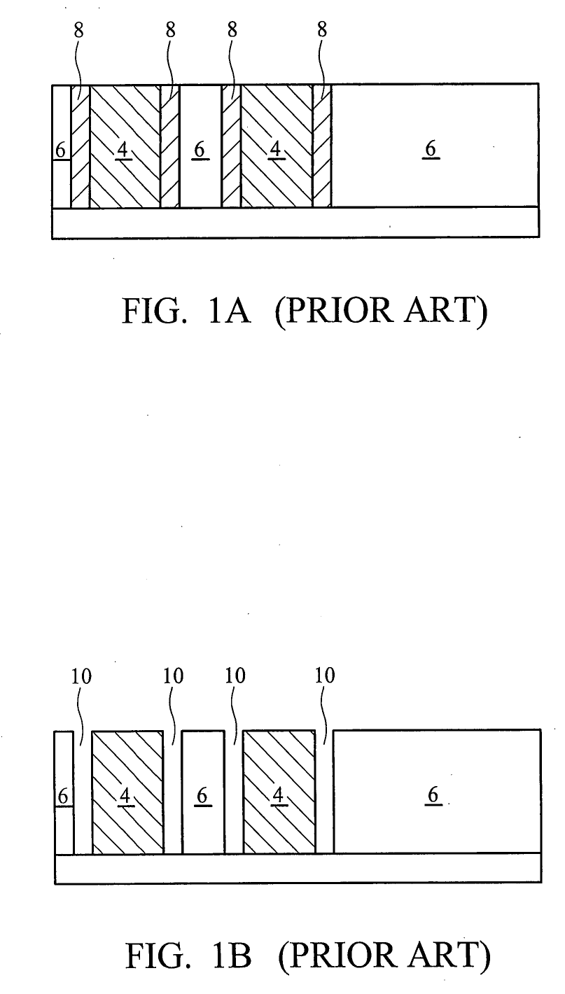

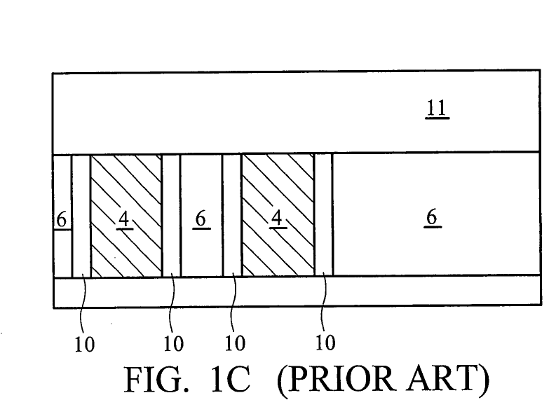

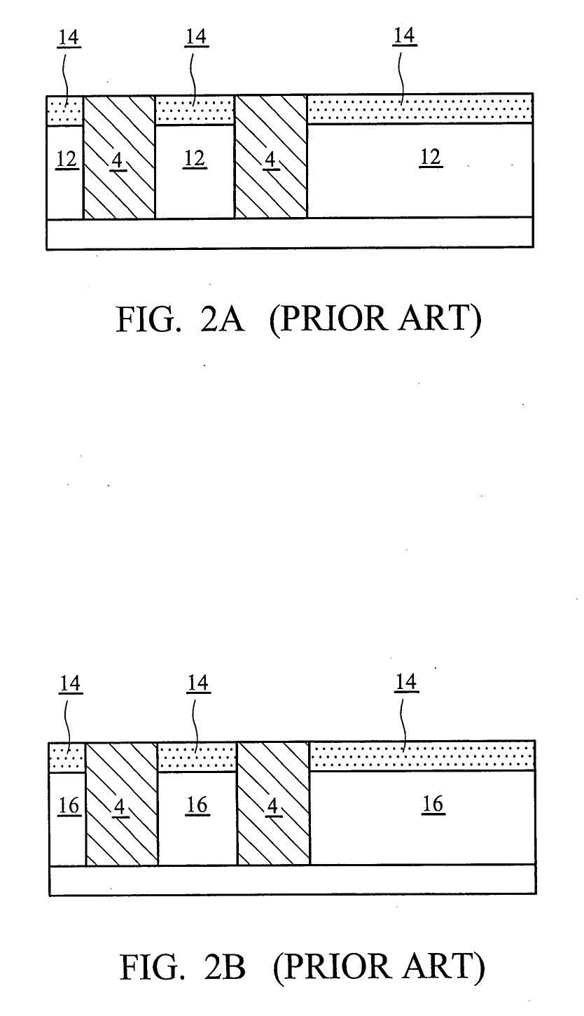

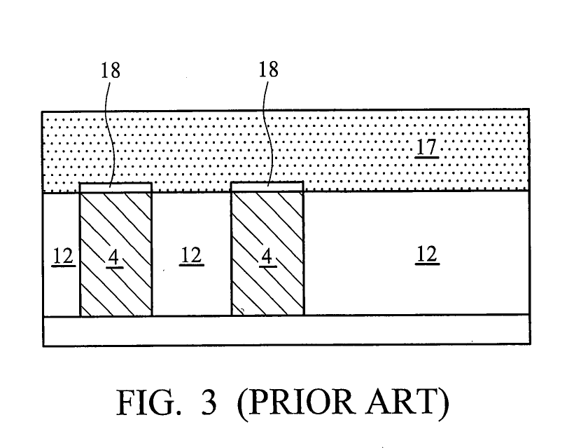

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

Interconnect structures with air-gaps and sidewall spacers are provided. The intermediate stages of manufacturing preferred embodiments of the present invention are illustrated. Throughout the various views and illustrative embodiments of the present invention, like reference numbers are used to designate like elements. In the following discussed embodiments, single damascene processes are discussed. One skilled in the art will realize that the teaching is readily available for dual damascene processes.

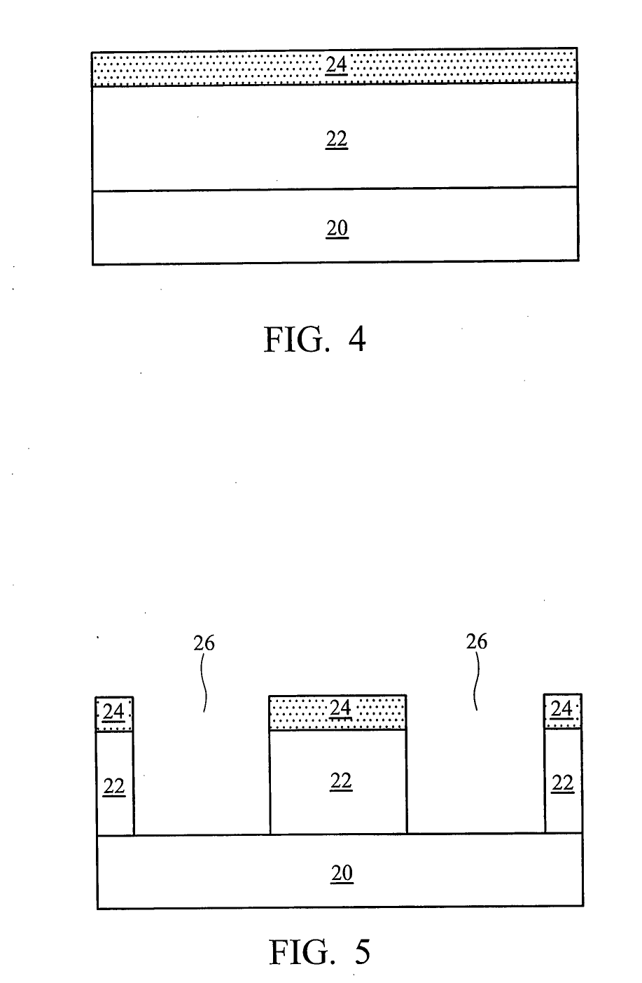

FIGS. 4 through 10 are cross-sectional views of intermediate stages in a first embodiment of the present invention. FIG. 4 illustrates a starting structure, which includes sacrificial layer 22 on base layer 20, and permeable hard mask layer 24 on sacrificial layer 22. Layers 20, 22 and 24 are formed over a substrate (not shown), which may be a single crystalline or a compound semiconductor substrate. Active devices (not shown) such as transistors may be formed on the semiconductor substrate. Base layer 20 may be known as a dielectric layer, such as an inter-layer dielectric, an inter-metal dielectric, and the like. Conductive features (not shown), such as contact plugs or vias, may be formed in base layer 20 and connected to the subsequently formed conductive lines.

In an exemplary embodiment, base layer 20 has a low dielectric constant (k value), preferably lower than about 3.0. Base layer 20 may include commonly used low-k dielectric materials such as carbon-containing dielectric materials, and may further include nitrogen, hydrogen, oxygen, and combinations thereof. In an embodiment, sacrificial layer 22 includes a polymer that may decompose and vaporize at an elevated temperature, for example, between 250° C. and 450° C. When sacrificial layer 22 decomposes, the polymer breaks down into smaller gas molecules that can diffuse through permeable hard mask layer 24. Exemplary materials of sacrificial layer 22 include polypropylene glycol (PPG), polybutadine (PB), polyethylene glycol (PEG), polycaprolactone diol (PCL), fluorinated amorphous carbon (a-FiC), silicon gel and organic silaxone. Sacrificial layer 22 is preferably formed by a spin-on process or a chemical vapor deposition (CVD) process. In other embodiments, sacrificial layer 22 can be removed by a wet or dry etching process, wherein the generated liquid or gases may also penetrate permeable hard mask layer 24, and be removed. In an exemplary embodiment, the etchable sacrificial layer 22 includes silicon oxide.

Permeable hard mask layer 24 allows the materials generated by the thermal-decomposition or etching process to penetrate through. Exemplary materials of hard mask layer 24 include Black Diamond™ (Applied Materials), SiLK™ (Dow Chemical Company), silicon oxycarbide, and combinations thereof. In an exemplary embodiment wherein permeable hard mask layer 24 comprises silicon oxycarbide, it may be formed using high-density plasma chemical vapor deposition (HDPCVD) process, and the process gases preferably include a Si-containing gas (for example, SiH₄), Ar and O₂. Permeable hard mask layer 24 preferably has a thickness of less than about 2000 Å, and more preferably between about 500 Å and about 1500 Å.

FIG. 5 illustrates the formation of trenches 26, which are preferably formed by applying and patterning a photoresist, and then etching layers 22 and 24. The photoresist is then removed.

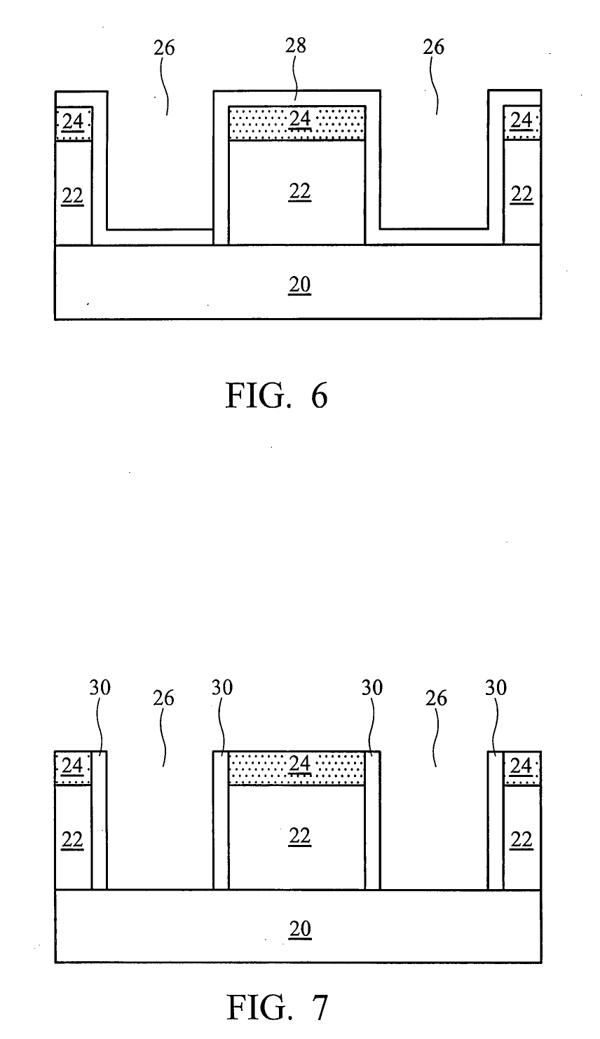

Spacer layer 28 is then deposited, as is shown in FIG. 6. Spacer layer 28 preferably comprises a dielectric material, such as Black Diamond™ (Applied Materials), SiO₂, SiON, SiC, SiCN and combinations thereof. Preferably, spacer layer 28 has a thickness of between about 50 Å and about 300 Å, and more preferably about 100 Å, although the preferred thickness is related to the scale of the formation technology. A patterning is then performed to remove horizontal portions of spacer layer 28, and the remaining vertical portions form spacers 30, as shown in FIG. 7. As is known in the art, the patterning of spacer layer 28 may be performed by etching or argon sputtering.

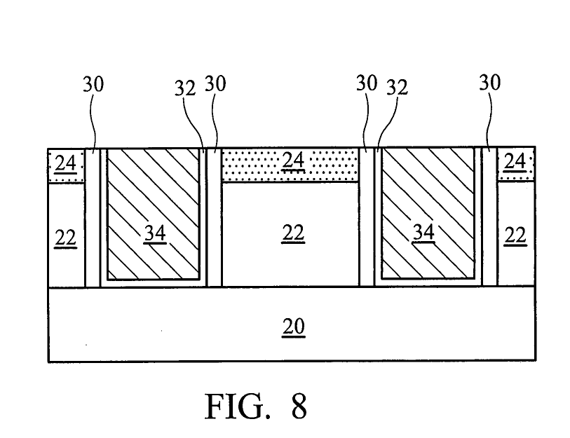

FIG. 8 illustrates the formation of conductive lines, including diffusion barrier layers 32 and metal lines 34, in trenches 26. Diffusion barrier layers 32 preferably include titanium, titanium nitride, tantalum, tantalum nitride, or other alternatives. Diffusion barrier layers 32 may be formed using physical vapor deposition (PVD) or one of the chemical vapor deposition (CVD) methods. The thickness of diffusion barrier layers 32 may be between about 20 Å and about 200 Å.

The material of metal lines 34 preferably includes copper or a copper alloy, although it may include other conductive materials, such as silver, gold, tungsten, aluminum, and the like. As is known in the art, the steps for forming diffusion barrier layers 32 and metal lines 34 may include blanket forming a barrier layer, depositing a thin seed layer of copper or copper alloy, and filling trenches 26 with a conductive material, such as copper or copper alloys, preferably by plating, thus metal lines 34 may be referred to as copper lines 34. A chemical mechanical polish (CMP) is then performed to remove the excess diffusion barrier layer and conductive material on permeable hard mask layer 24, leaving diffusion barrier layers 32 and copper lines 34 only in trenches 26. Alternatively, diffusion barrier layers 32 are not formed, and spacers 30 act as diffusion barrier layers.

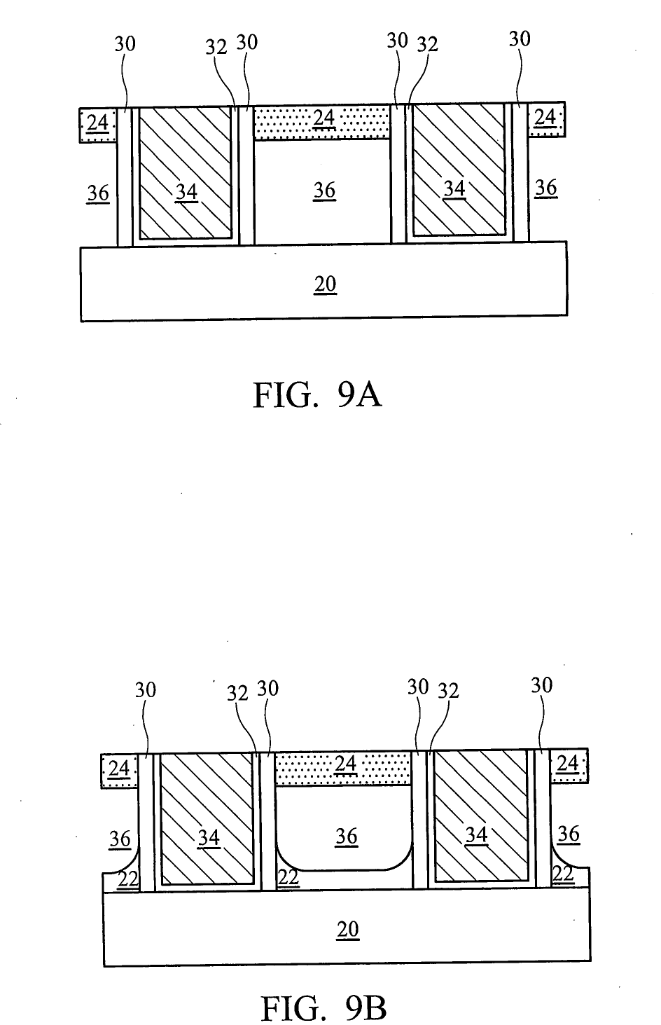

As shown in FIG. 9A, sacrificial layer 22 is decomposed and turned into a vapor with molecules small enough to diffuse through the permeable hard mask layer 24. Air-gaps 36 are thus formed. The decomposition and vaporization are preferably performed by a heating process at a relatively elevated temperature. In an exemplary embodiment, the temperature is between about 200° C. and about 450° C. Alternatively, sacrificial layer 22 is removed by wet or dry etching, wherein the by-products (liquids or gases) can penetrate through permeable hard mask layer 24. Since sacrificial layer 22 is removed form top, a lower portion of sacrificial layer 22 may be left, as is shown in FIG. 9B.

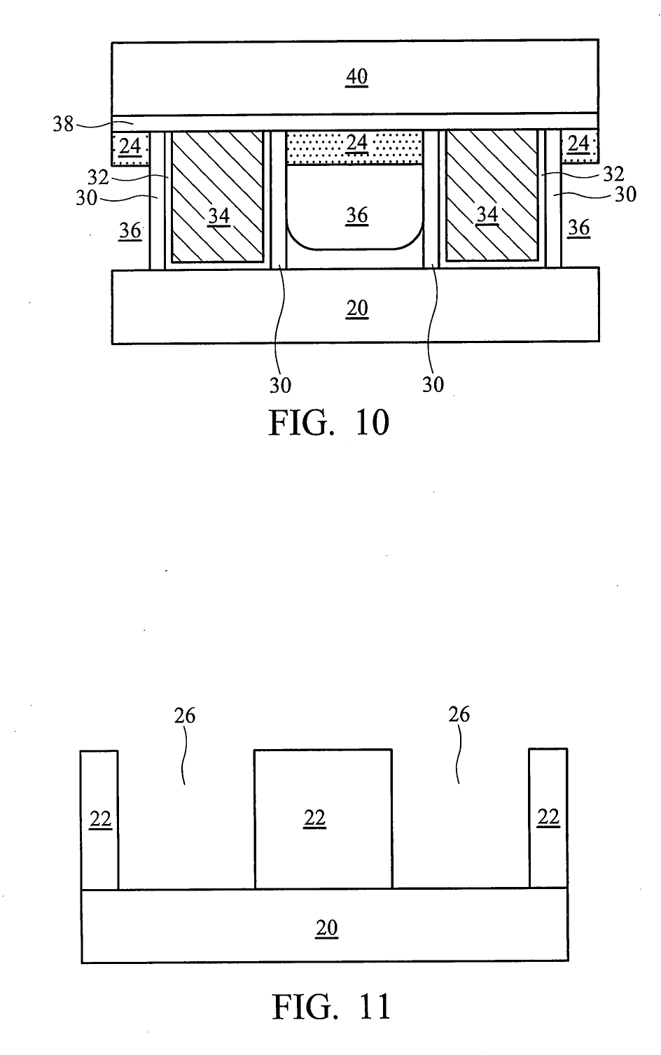

Referring to FIG. 10, etch stop layer 38 and inter-metal dielectric layer 40 are formed. Preferably, etch stop layer 38 is formed of SiC, SiCN or other commonly used materials. Inter-metal dielectric layer 40 preferably comprises low-k dielectric materials such as carbon-containing materials. In subsequent process steps, vias and overlying metal lines may be formed to continue the formation process of interconnect structure.

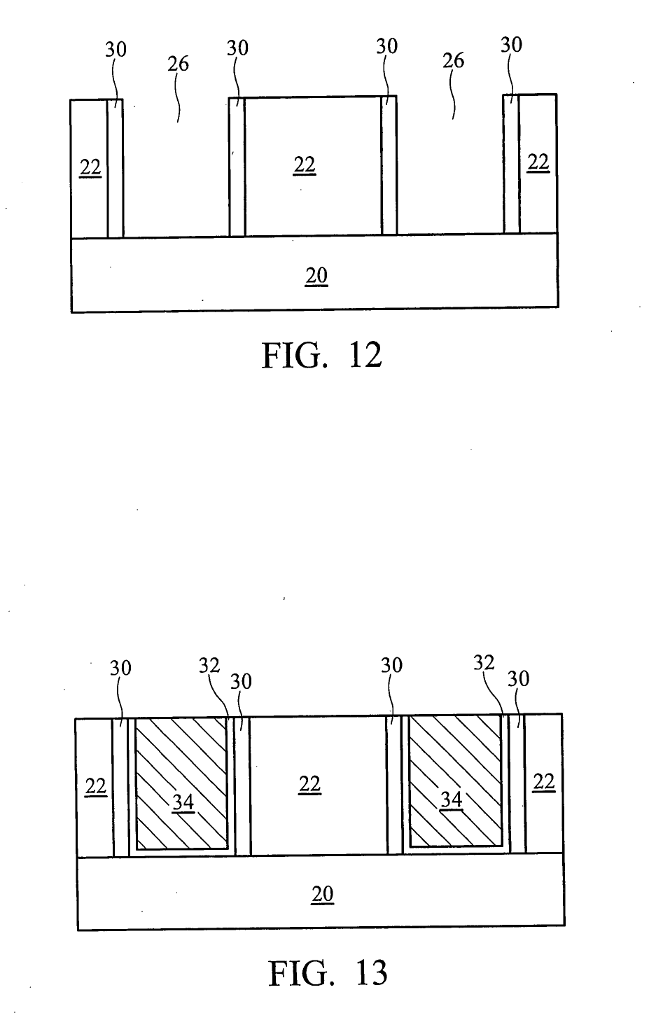

FIGS. 11 through 16 illustrate a second embodiment of the present invention, wherein like reference numerals in the second embodiment are used to indicate like elements in the first embodiment. Unless specifically noted, essentially same materials and same formation methods apply to the formation of like elements in both the first and the second embodiments. Referring to FIG. 11, base layer 20 and sacrificial layer 22 are formed. Trenches 26 are then formed in sacrificial layer 22. Spacers 30 are then formed on sidewalls of trenches 26, as is shown in FIG. 12.

FIG. 13 illustrates the formation of diffusion barrier layers 32 and metal lines 34 in trenches 26. Cap layers 44 are then formed on metal lines 34, and possibly on top edges of diffusion barrier layers 32, as shown in FIG. 14. Cap layers 44 may be formed of CoP, CoB, CoWP, CoWB, NiWP, CoSnP, NiWB, CuSi, ZrN, NiMoP, and combinations thereof. The preferred methods include electroless plating, wherein cap layers 44 are selectively formed on metal lines 34 (and diffusion barrier layers 32), but not dielectric materials.

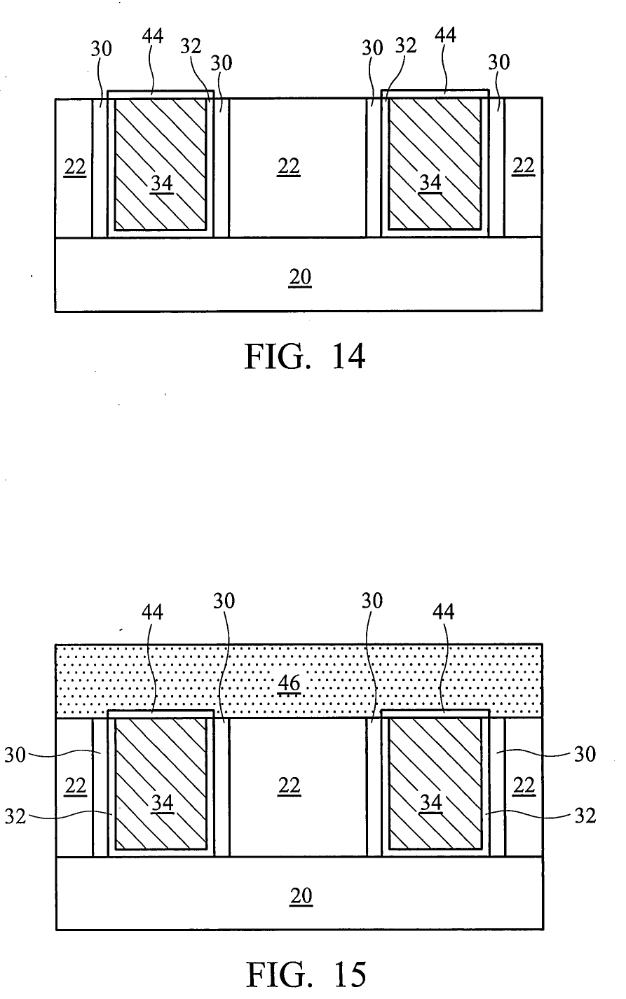

Referring to FIG. 15, permeable inter-metal dielectric 46 is formed. In the preferred embodiment, permeable inter-metal dielectric 46 comprises Black Diamond, SiLK™ (Dow Chemical Company), silicon oxycarbide, and combinations thereof. The preferred thickness of permeable inter-metal dielectric 46 is between about 500 Å and about 2000 Å.

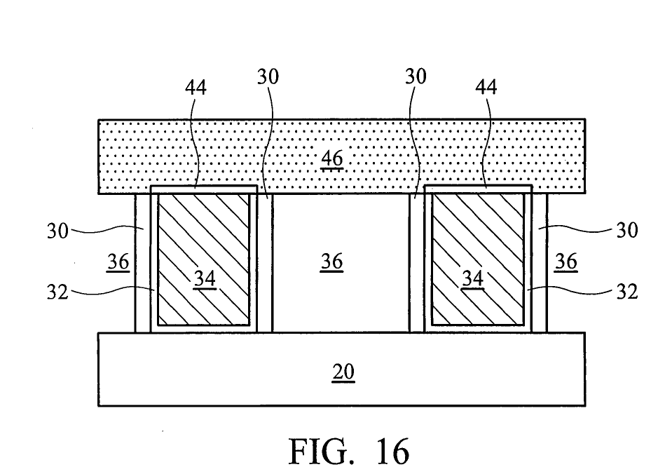

FIG. 16 illustrates the removal of sacrificial layer 22. In the case sacrificial layer 22 is formed of thermal-decomposable polymers, the substrate is heated to decompose sacrificial layer 22, forming air-gaps 36. In other embodiments, a dry etch or a wet etch is performed, and the by-products are removed through permeable inter-metal dielectric 46. The details for removing sacrificial layer 22 have been discussed in the first embodiment, and thus are not repeated herein.

The embodiments of the present invention have several advantageous features. By forming air-gaps, the equivalent k values of dielectric materials in the interconnect structure are reduced, sometimes to as low as about 2.0. Spacers 30 provide back pressure to metal lines 34 and diffusion barrier layers 32, and thus electro-migration and time dependent dielectric breakdown (TBBD) performance of the interconnect structure is improved. A further advantageous feature is that in the case the overlying via is misaligned, it is likely that the vias will land on spacers 30 instead of air-gaps 36. The performance and reliability of the interconnect structure is thus improved.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. An integrated circuit structure comprising:
a conductive line;
a sidewall spacer on a sidewall of the conductive line, wherein the sidewall spacer comprises a dielectric material;
an air-gap horizontally adjoining the sidewall spacer; and
a dielectric layer on the air-gap.

2. The integrated circuit structure of claim 1, wherein the dielectric layer is a permeable hard mask layer, and wherein the sidewall spacer extends on a sidewall of the dielectric layer.

3. The integrated circuit structure of claim 2 further comprising an etch stop layer on the dielectric layer and the conductive line.

4. The integrated circuit structure of claim 1 further comprising a cap layer on the conductive line.

5. The integrated circuit structure of claim 4 further comprising an etch stop layer over the dielectric layer and the cap layer.

6. The integrated circuit structure of claim 1, wherein the conductive line comprises a copper line on a diffusion barrier layer, and wherein the diffusion barrier layer is in physical contact with the sidewall spacer.

7. The integrated circuit structure of claim 1, wherein the dielectric layer is a permeable inter-metal dielectric, and wherein the dielectric layer extends over a top edge of the sidewall spacer.

8. The integrated circuit structure of claim 7 further comprising a cap layer on the conductive line and under the dielectric layer.

9. The integrated circuit structure of claim 1 further comprising:
an additional conductive line on an opposite side of the air-gap than the conductive line, wherein the air-gap horizontally adjoins the additional conductive line; and
an additional sidewall spacer on a sidewall of the additional conductive line.

10. The integrated circuit structure of claim 1, wherein the sidewall spacer does not extend under the conductive line.

11. The integrated circuit structure of claim 1, wherein an upper portion of the sidewall spacer horizontally adjoins the air-gap, and wherein a lower portion of the sidewall spacer horizontally adjoins a low-k dielectric layer underlying the air-gap.

12. The integrated circuit structure of claim 1, wherein the sidewall spacer comprises a material selected from the group consisting essentially of Black Diamond, SiO₂, SiON, SiC, SiCN, and combinations thereof.

13. The integrated circuit structure of claim 1, wherein the sidewall spacer has a thickness of between about 50 Å and about 300 Å.

14. An integrated circuit structure comprising:
a first conductive line;
a first sidewall spacer on a sidewall of the first conductive line;
a second conductive line horizontally spaced apart from the first conductive line;
a second sidewall spacer on a sidewall of the second conductive line;
an air-gap horizontally adjoining the first and the second sidewall spacers; and
a permeable dielectric layer on and adjoining the air-gap.

15. The integrated circuit structure of claim 14 further comprising an etch stop layer on the permeable dielectric layer and the conductive line, wherein the permeable dielectric layer is a permeable hard mask layer, and wherein the sidewall spacer extends on a sidewall of the permeable hard mask layer.

16. The integrated circuit structure of claim 14 further comprising a cap layer on the conductive line, wherein the permeable dielectric layer is a permeable inter-metal dielectric, and wherein the permeable inter-metal dielectric is over a top edge of the sidewall spacer.

17. The integrated circuit structure of claim 14 further comprising a low-k dielectric layer underlying the conductive line and the air-gap.

18. An integrated circuit structure comprising:
a conductive line;
a sidewall spacer on a sidewall of the conductive line;
an air-gap horizontally adjoining the sidewall spacer;
a permeable mask directly on the air-gap, wherein the sidewall spacer extends on a sidewall of the permeable mask;
an etch stop layer on the conductive line and the permeable mask; and
an inter-metal dielectric over the conductive line and the permeable mask.

19. The integrated circuit structure of claim 18, wherein the permeable mask comprises a material selected from the group consisting essentially of Black Diamond, SiLK™ (Dow Chemical Company), silicon oxycarbide, and combinations thereof.

20. The integrated circuit structure of claim 18, wherein the sidewall spacer comprises a material selected from the group consisting essentially of Black Diamond, SiO2, SiON, SiC, SiCN, and combinations thereof.

21. The integrated circuit structure of claim 18, wherein the sidewall spacer has a thickness of between about 50 Å and about 300 Å.
